(19) United States
(12) Patent Application Publication
(10) Pub. No.: US 2008/0168204 A1
(43) Pub. Date: Jul. 10, 2008

(54) Information Handling System Card

(75) Inventors: Andrew Thomas Sultenfuss, Leander, TX (US); James R. Utz, Round Rock, TX (US)

Correspondence Address: HAYNES AND BOONE, LLP, 901 Main Street, Suite 3100, Dallas, TX, 75202, US

(73) Assignee: DELL PRODUCTS L.P., Round Rock, TX (US)

(21) Appl. No.: 11/619,970

(22) Filed: Jan. 4, 2007

(51) Int. Cl. G06F 13/00; H05K 7/10

(52) U.S. Cl. 710/301; 710/302

(57) ABSTRACT

An information handling system card (IHS card) includes a base having a first end. A first card connector is located on the first end and is operable to electrically couple to a first information handling system connector (IHS connector) located on an information handling system (IHS), wherein the first IHS connector is operable to electrically couple an IHS card compliant to the ExpressCard™ Standard to the IHS. A second card connector is located on the first end and adjacent to the first card connector, wherein the second card connector is operable to electrically couple to a second IHS connector located on the IHS. The IHS card may be coupled to an IHS in order to provide greater functionality to the IHS than that provided by a conventional ExpressCard™.

### BACKGROUND

The present disclosure relates generally to information handling systems, and more particularly to an enhanced information handling system card.

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Conventional IHSs typically include the ability to interface with information handling system cards (IHS cards) that can expand the capabilities of the IHS. Such expanded capabilities may include, for example, additional memory, wired communications capabilities, wireless communication capabilities, mass storage, I/O capabilities, and a variety of other capabilities known in the art. IHS cards typically include printed circuit board(s) encased in a housing and are produced in a variety of form factors. Each IHS card typically includes a card connector located at one end of the housing that facilitates a convenient pluggable connection to a host IHS. The host IHS may be, for example, a personal computer (PC), a notebook computer or a desktop, a camera, a phone, or a variety of other host IHSs known in the art that provide an information handling system connector (IHS connector) for electrically coupling the IHS to an IHS card.

Previously a number of manufacturers produced a variety of IHS cards that were often incompatible. As such, IHS cards today are typically built in accordance with promulgated standards so as to insure physical and electrical compatibility. Portable Computer Memory Card International Association (PCMCIA) is one organization that promulgates such standards, and it has published industry standards for the form factor, connector styles, and electrical interfaces of a type of IHS cards known as PC Cards. The standards also specify requirements for the host IHS in that the IHS must have an IHS connector operable to electrically and physically couple a standard compliant PC card to the IHS. One example of a standard promulgated by the PCMCIA is the ExpressCard™ Standard Release 1.0 (available at www.expresscard.org). The ExpressCard™ Standard includes two module types: an ExpressCard/54™ and ExpressCard/34™. Each of the module types is an IHS card with the same physical interface to the IHS, but the two modules types vary in form factor. The ExpressCard/34™ has a narrower width of 34 mm for smaller IHSs, while the larger ExpressCard/54™ has a width of 54 mm and can accommodate more applications as well as allow for increased dissipation of thermal energy. An ExpressCard™ Standard compliant host IHS connector can electrically couple an IHS to an ExpressCard/54™ as well as an ExpressCard/34™. The ExpressCard™ Standard requires the IHS connector support interfaces for Peripheral Component Interconnect (PCI) Express and Universal-Serial-Bus (USB) 2.0. USB and PCI Express are widely used serial-interface standard buses for connecting external devices to an IHS. An ExpressCard™ supports at least one of these two interfaces. Though advantageous in many ways, an ExpressCard™, like other industry standard IHS cards, is limited in the functional interfaces provided. For instance, an ExpressCard™ does not provide cost effective video output with performance that would be satisfying to a user. An ExpressCard™ can not provide power to a notebook computer IHS sufficient to be the sole power source for the notebook. As such, users are required to connect the notebook computer to AC power through a notebook computer AC Adapter in order to provide the notebook computer sufficient power. An Expresscard™ is also limited in the power it can transmit from an IHS to a peripheral device. When a user is using a peripheral device with high power requirements, such as a physics processing unit (PPU), TV tuner card, or miniature projector for example, this is especially disadvantageous to the user. Furthermore, an Expresscard™ is limited in the antenna size, signal strength, and frequencies it can provide to the IHS for wireless communications.

Accordingly, it would be desirable to provide an enhanced IHS card absent the disadvantages discussed above.

### SUMMARY

According to one embodiment, an IHS card includes a base comprising a first end, a first card connector located on the first end and operable to electrically couple to an IHS connector located on an IHS, wherein the first IHS connector is operable to electrically couple an IHS card compliant to the ExpressCard™ Standard to the IHS, and a second card connector located on the first end and adjacent to the first card connector, wherein the second card connector is operable to electrically couple to a second IHS connector located on the IHS.

### BRIEF DESCRIPTION OF THE DRAWINGS

FIG. 1 is a schematic view illustrating an embodiment of an IHS.

FIG. 2 is a perspective view illustrating an embodiment of a conventional ExpressCard/54™.

FIG. 3 is a perspective view illustrating an embodiment of a conventional ExpressCard/34™.

FIG. 4a is a perspective view illustrating an embodiment of an enhanced IHS card.

FIG. 4b is a perspective view illustrating an embodiment of the enhanced IHS card of FIG. 4a.

FIG. 4c is a schematic view illustrating an embodiment of the enhanced IHS card of FIGS. 4a and 4b.

FIG. 5a is a perspective view illustrating an embodiment of a IHS chassis used with the enhanced IHS card of FIGS. 4a, 4b and 4c.

FIG. 5b is a cut-away perspective view illustrating an embodiment of IHS connectors in the IHS chassis of FIG. 5a.

FIG. 5c is a schematic illustrating an embodiment of the IHS chassis of FIGS. 5a and 5b.

FIG. 6a is a flow chart illustrating of an embodiment of a method of coupling an IHS and IHS card.

FIG. 6b is a perspective view illustrating an embodiment of the enhanced IHS card of FIGS. 4a, 4b and 4c being coupled to the chassis of FIGS. 5a, 5b and 5c.

FIG. 6c is a schematic illustrating an embodiment of the enhanced IHS card FIGS. 4a, 4b and 4c coupled to the IHS chassis of FIGS. 5a, 5b and 5c.

FIG. 6d is a perspective view illustrating an embodiment of the conventional ExpressCard/54™ of FIG. 2 being coupled to the chassis of FIGS. 5a, 5b and 5c.

FIG. 6e is a perspective view illustrating an embodiment of the conventional ExpressCard/34™ of FIG. 3 being coupled to the chassis of FIGS. 5a, 5b and 5c.

### DETAILED DESCRIPTION

For purposes of this disclosure, an IHS may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a network server or storage device, a switch router or other network communication device, or any other suitable device and may vary in size, shape, performance, functionality, and price. The IHS may include memory, one or more processing resources such as a central processing unit (CPU) or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communications between the various hardware components.

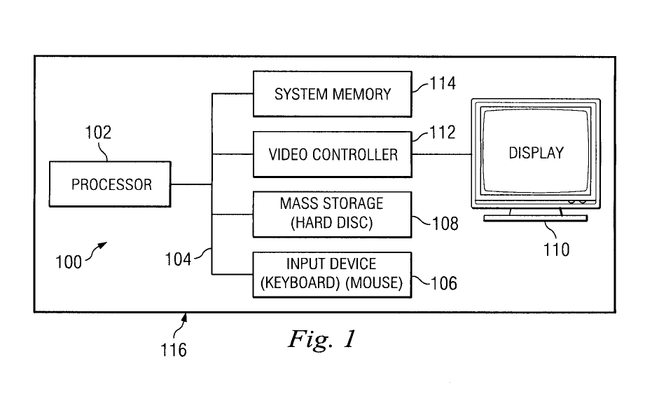

In one embodiment, IHS 100, FIG. 1, includes a processor 102, which is connected to a bus 104. Bus 104 serves as a connection between processor 102 and other components of computer system 100. An input device 106 is coupled to processor 102 to provide input to processor 102. Examples of input devices include keyboards, touchscreens, and pointing devices such as mouses, trackballs and trackpads. Programs and data are stored on a mass storage device 108, which is coupled to processor 102. Mass storage devices include such devices as hard disks, optical disks, magneto-optical drives, floppy drives and the like. IHS 100 further includes a display 110, which is coupled to processor 102 by a video controller 112. A system memory 114 is coupled to processor 102 to provide the processor with fast storage to facilitate execution of computer programs by processor 102. In an embodiment, a chassis 116 houses some or all of the components of IHS 100. It should be understood that other buses and intermediate circuits can be deployed between the components described above and processor 102 to facilitate interconnection between the components and the processor 102.

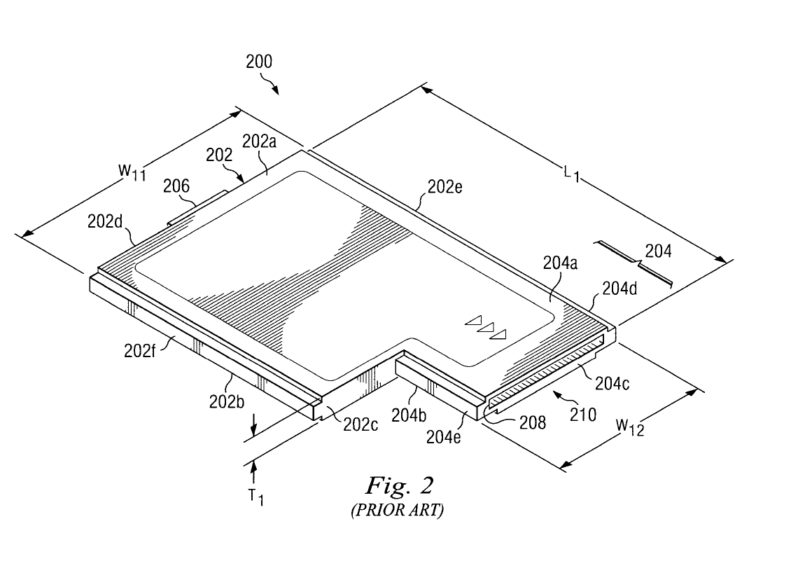

Referring now to FIGS. 2 and 3, a plurality of conventional IHS cards compliant to the ExpressCard™ Standard are illustrated. FIG. 2 illustrates a conventional ExpressCard/54™ IHS card 200. The IHS card 200 includes a base 202 having a top surface 202a, a bottom surface 202b located opposite the top surface 202a, a front edge 202c extending between the top surface 202a and the bottom surface 202b, a rear edge 202d located opposite the front edge 202c and extending between the top surface 202a and bottom surface 202b, and a pair of opposing side edges 202e and 202f extending between the top surface 202a, the bottom surface 202b, the front edge 202c, and the rear edge 202d. A connector extension member 204 extends from the front edge 202c of the base 202 adjacent the side edge 202e. The connector extension member 204 includes a top surface 204a substantially coplanar with the top surface 202a, a bottom surface 204b substantially coplanar with the bottom surface 202b and located opposite the top surface 204a, a front edge 204c extending between the top surface 204a and the bottom surface 204b, a side edge 204d substantially coplanar with the side edge 202e and extending between the top surface 204a, the bottom surface 204b, and the front edge 204c, and a second side edge 204e oriented substantially perpendicular to the front edge 202c of the base 202 and extending between the top surface 204a, the bottom surface 204b, and the front edge 204c. A card connector 206 is centrally located on the rear edge 202d. The card connector 206 style and functionality are not defined by the ExpressCard™ Standard. In an embodiment, the card connector 206 may be an antenna, a connector for a peripheral device including a port replicator or docking station, a Bluetooth connector, a connector for wired communications, or be a variety of other connectors as known in the art. In an embodiment, the rear edge 202d may include no card connector. The connector extension member 204 defines a channel 208 extending from the front edge 204c and into the connector extension member 204 and a card connector 210 is located in the channel 208. The card connector 210 is a beam-on-blade type connector with 26 contact positions. The style of the card connector including the connector type (e.g. beam-on-blade), position count, and pitch of the positions is defined by the ExpressCard™ Standard in the illustrated embodiment. The IHS card 200 has a rear width W₁₁, which is the distance between the side edge 202e and the side edge 202f, of approximately 54 mm. The connector extension member 204 has a front width W₁₂, which is the distance between the side edge 204d and the side edge 204e, of approximately 34 mm. The IHS card 200 has a thickness T₁, which is the distance between the top surface 202a and the bottom surface 202b of the base 202 as well as the distance between the top surface 204a and the bottom surface 204b of the connector extension member 204, of approximately 5 mm. The IHS card 200 has a length L:, which is the distance between the front edge 204c and the rear edge 202d, of approximately 75 mm. Other embodiments of the conventional IHS card may have varying lengths depending on the functionality needed on the IHS card including, for example, the type of connector extending from the rear edge 302d.

FIG. 3 illustrates a conventional ExpressCard/34™ IHS card 300. The IHS card 300 includes a base 302 having a top surface 302a, a bottom surface 302b located opposite the top surface 302a, a front edge 302c extending between the top surface 302a and the bottom surface 302b, a rear edge 302d located opposite the front edge 302c and extending between the top surface 302a and the bottom surface 302b, and a pair of opposing side edges 302e and 302f extending between the top surface 302a, the bottom surface 302b, the front edge 302c, and the rear edge 302d. The base 302 defines a channel 304 extending from the front edge 302c and into the base 302, and a card connector 306 is located in the channel 304. The card connector 306 is a beam-on-blade type connector with 26 contact positions. The style of the card connector 306 including the connector type, position count, and pitch of the positions is defined by the ExpressCard™ Standard in the illustrated embodiment. A card connector 308 is centrally located on the rear edge 302d. The card connector 308 style and functionality are not defined by the ExpressCard Standard. In an embodiment, the card connector 308 may be an antenna, a connector for a peripheral device including a port replicator or docking station, a Bluetooth connector, a connector for wired communications, or be a variety of other connectors as known in the art. In an embodiment, the rear edge 302d may include no card connector. The IHS card 300 has a width W₂, which is the distance between the opposing side edges 302e and 302f, of approximately 34 mm. The IHS card 300 has a thickness T₂, which is the distance between the top surface 302a and the bottom surface 302b, of approximately 5 mm. The IHS card 300 has a length L₂, which is the distance between the front edge 302c and the rear edge 302d, of approximately 75 mm. Other embodiments of the conventional IHS card however may have varying lengths depending on the functionality needed on the IHS card including, for example, the type of connector extending from rear edge 302d.

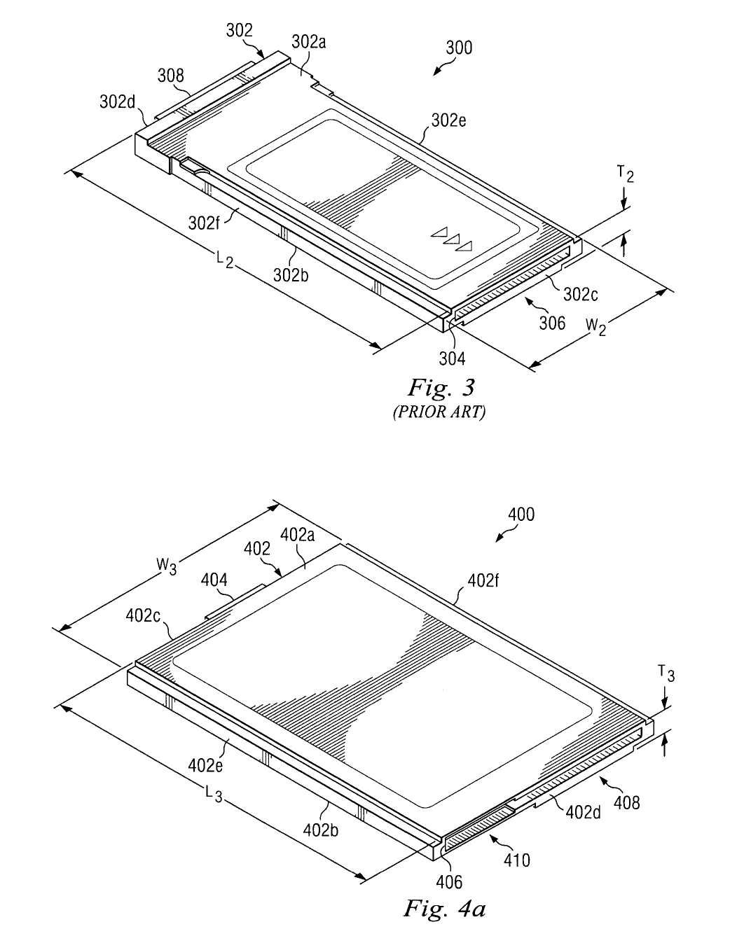

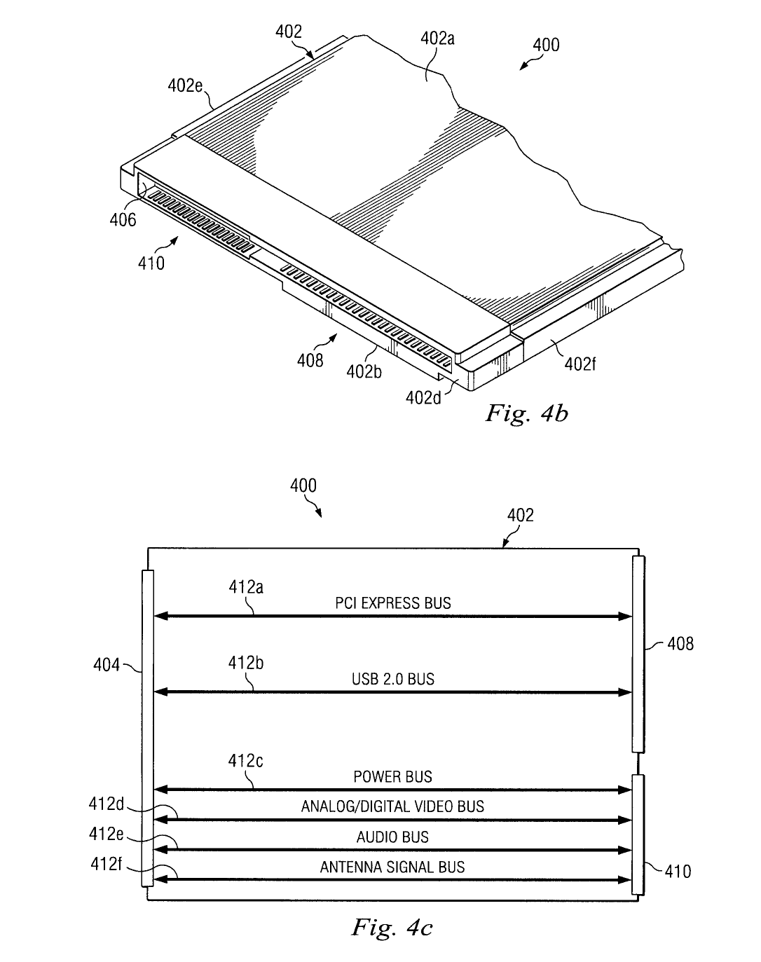

Referring now to FIGS. 4a, 4b and 4c, an enhanced IHS card 400 is illustrated. The IHS card 400 includes a base 402 having a top surface 402a, a bottom surface 402b located opposite the top surface 402a, a rear edge 402c extending between the top surface 402a and the bottom surface 402b, a front edge 402d located opposite the rear edge 402c and extending between the top surface 402a and the bottom surface 402b, and a pair of opposing side edges 402e and 402f extending between the top surface 402a, the bottom surface 402b, the rear edge 402c, and the front edge 402d. A card connector 404 is centrally located on the rear edge 402c. In an embodiment, the card connector 404 may be an antenna, a connector for a peripheral device including a port replicator or docking station, a Bluetooth connector, a connector for wired communications, or be a variety of other connectors as known in the art. In an embodiment, the rear edge 402c may contain no card connector. A channel 406 is defined by the base 402 and extends from the front edge 402d into the base 402. A first card connector 408 is located in the channel 406. A second card connector 410 is located in the channel 408 adjacent the first card connector 408. The first card connector 408 is a 26 contact position beam-on-blade type connector. The card connector 408 style is defined by industry standard, such as for example, the ExpressCard™ Standard as illustrated in this embodiment. As such the card connector 408 connector style, including position count, connector type, and pitch, is substantially similar to the card connector 210 of the conventional IHS card 200, described above with regard to FIG. 2, and the card connector 306 of the conventional IHS card 300, described above with regard to FIG. 3. In an embodiment, the second card connector 410 is a 40 contact position, with dual row contacts at a 0.8 mm pitch, beam-on-blade type connector as illustrated in FIG. 4b. (The upper row of 20 contact positions is not shown.) Other connector styles are possible. The IHS card 400 has a width W₃, which is the distance between the opposing side edges 402e and 402f, of approximately 54 mm. The IHS card 400 has a thickness T₃, which is the distance between the top surface 402a and the bottom surface 402b, of approximately 5 mm. In the present embodiment, the IHS card 400 has a length L₃, which is the distance between rear edge 402c and front edge 402d, of approximately 75 mm. In other embodiments, the enhanced IHS card 400 length L₃ will vary depending on the functionality needed on the IHS card including, for example, the type of connector extending from rear edge 402c. Other embodiments using alternative form factors, number of connectors, and style of connectors for the enhanced IHS card are possible.

The enhanced IHS card 400 includes a plurality of buses 412a, 412b, 412c, 412d, 412e and 412f extending between the connectors 404, 408 and 410. A PCI Express bus 412a is electrically coupled to the first card connector 408 and the third card connector 404 and operable to transmit a signal between the first card connector 408 and the third card connector 404. A USB 2.0 bus 412b is electrically coupled to the first card connector 408 and the third card connector 404 and operable to transmit a signal between the first card connector 408 and the third card connector 404. A power bus 412c is electrically coupled to the second card connector 410 and the third card connector 404 and operable to transmit power between the second card connector 410 and the third card connector 404. A video bus 412d is electrically coupled to the second card connector 410 and the third card connector 404 and operable to transmit a signal, such as, for example, an analog signal or a digital signal, between the second card connector 410 and the third card connector 404. An audio bus 412e is electrically coupled to the second card connector 410 and the third card connector 404 and operable to transmit a signal between the second card connector 410 and the third card connector 404. An antenna signal bus 412f is electrically coupled to the second card connector 410 and the third card connector 404 and operable to transmit a signal between the second card connector 410 and the third card connector 404. Additional buses may be present and provide additional functionality to the IHS card 400 in a variety of manners as known in the art. The additional buses may couple the first connector 408 and the third connector 404, the second connector 410 and the third connector 404, or electrically couple a device located within the IHS card 400 to one or more of the card connectors 408, 410 and 404. In an embodiment, one or more of the buses illustrated on the enhanced IHS 400 may not be present. However, the functional interfaces provided by the first connector 408 are in compliance with an IHS card industry standard, in this embodiment the ExpressCard™ Standard.

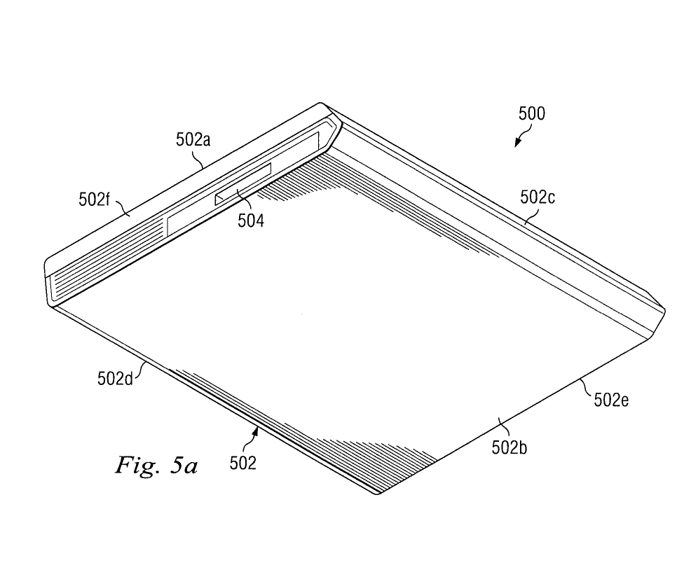

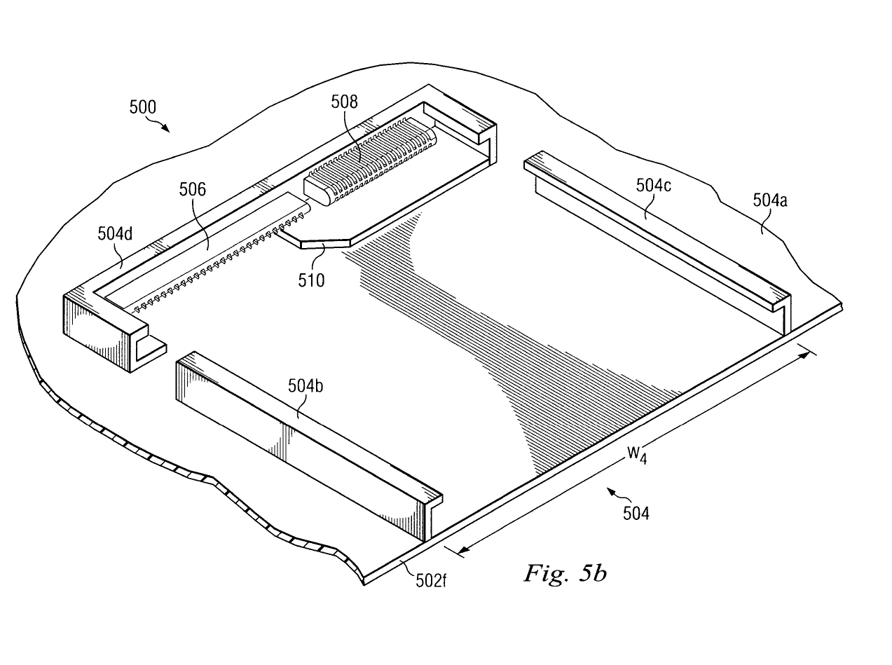

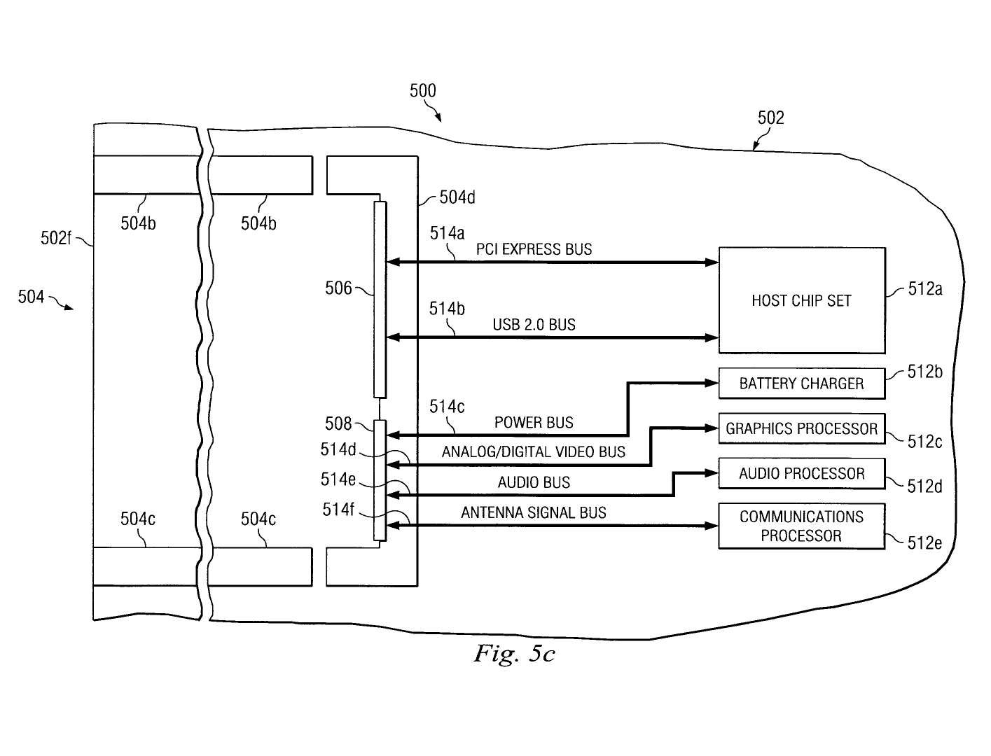

Referring now to FIGS. 5a, 5b and 5c, an IHS chassis 500 is illustrated. In an embodiment, the IHS chassis 500 may be, for example, the chassis 116 described above with respect to FIG. 1, and may house some or all of the components of the IHS 100, also described above with respect to FIG. 1. The IHS chassis 500 includes a base 502 have a top surface 502a, a bottom surface 502b located opposite the top surface 502a, a front edge 502c extending between the top surface 502a and the bottom surface 502b, a rear edge 502d located opposite the front edge 502c and extending between the top surface 502a and the bottom surface 502b, and a pair of opposing side edges 502e and 502f extending between the top surface 502a, the bottom surface 502b, the front edge 502c, and the rear edge 502d.

An IHS card slot 504 is defined by the base 502 and extends from the side edge 502f and into the base 502. A slot bottom surface 504a extends from edge 502f into the base 502, two opposing side rails 504b and 504c extend from the slot bottom surface 504a and the side edge 502f, and a rear member 504d extends from the slot bottom surface 504a and between the side rails 504b and 504c. A first IHS connector 506 and a second IHS connector 508 extend from the rear member 504d with the second IHS connector 508 located adjacent the first IHS connector 506. The first IHS connector 506 style is defined by an industry standard for IHS cards. In the illustrated embodiment, the first IHS connector 506 is a 28 position beam-on-blade type connector as defined by the ExpressCard™ Standard. The second IHS connector 508 is a 40 contact position, with dual row contacts at a 0.8 mm pitch, beam-on-blade type connector. Other connector styles for the second IHS connector 508 or other locations of the first IHS connector 506 and the second IHS connector 508 that are possible. A guide member 510 extends from the rear member 504d. The IHS card slot 504 has a width W₄, which is the distance between the opposing side rails 504b and 504c, of just over approximately 54 mm.

The IHS chassis 500 may include a plurality of IHS components such as, for example, a host chip set 512a, a battery charger 512b, a graphics processor 512c, an audio processor 512d, a communications processor 512e, and a variety of other components such as those described above in reference to FIG. 1. In an embodiment, the host chip set 512a may include two main motherboard chips, such as, for example, a memory controller hub and an I/O controller hub. Though illustrated as discrete components, the processors and devices shown may be combined into one or several components. A PCI Express bus 514a is electrically coupled to the first IHS connector 506 and is operable to transmit a signal between the first IHS connector 506 and the host chip set 512a. A USB 2.0 bus 514b is electrically coupled to the first IHS connector 506 and is operable to transmit a signal between the first IHS connector 506 and the host chip set 512a. In the embodiment, the IHS chassis 500 is compliant to the ExpressCard™ Standard and as such provides the electrical interfaces, including the PCI Express bus 514a and the USB 2.0 bus 514b, required by the Standard through the first IHS connector 506. A power bus 514c is electrically coupled to the second IHS connector 508 and is operable to transmit power between the second IHS connector 508 and the battery charger 512b. A video bus 514d is electrically coupled to the second IHS connector 508 and is operable to transmit a signal, such as, for example, an analog signal or a digital signal, between the graphics processor 512c and the second IHS connector 508. An audio bus 514e is electrically coupled to the second IHS connector 508 and is operable to transmit a signal between the audio processor 512d and the second IHS connector 508. An antenna signal bus 514f is electrically coupled to the second card connector 508 and is operable to transmit a signal between the second IHS connector 508 and the communications processor 512e. Additional buses and components may be present and provide additional capability to the IHS including additional functional interfaces through the IHS connectors 506 and 508.

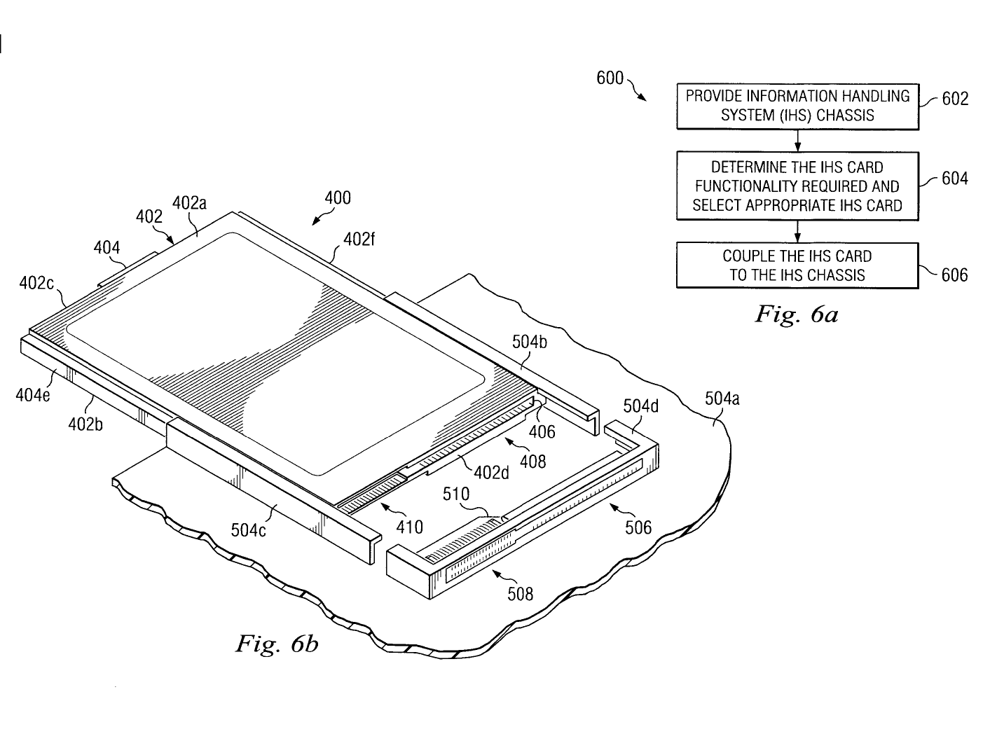

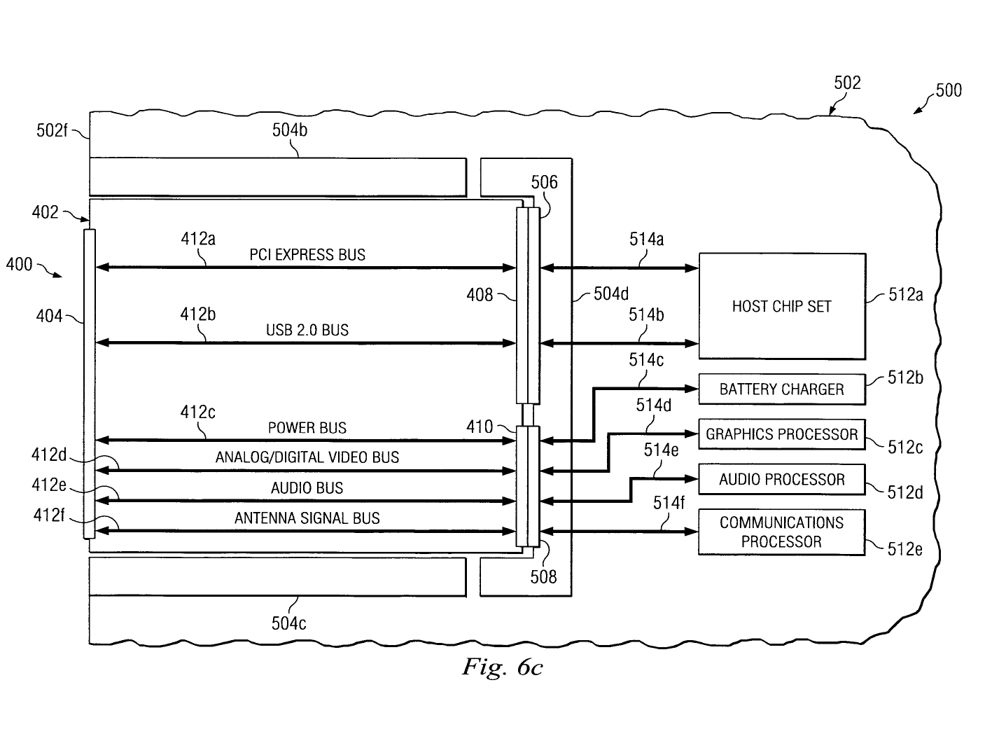

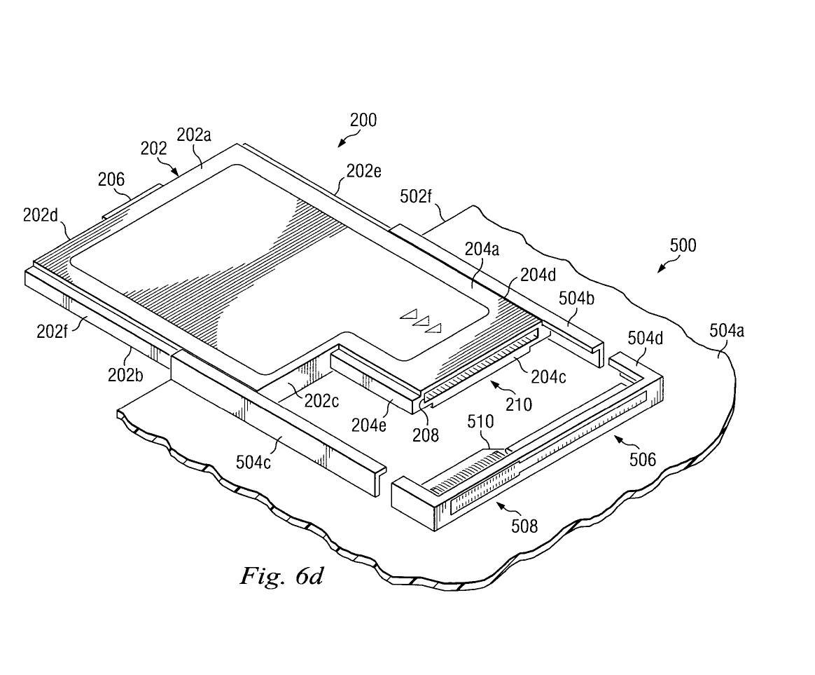

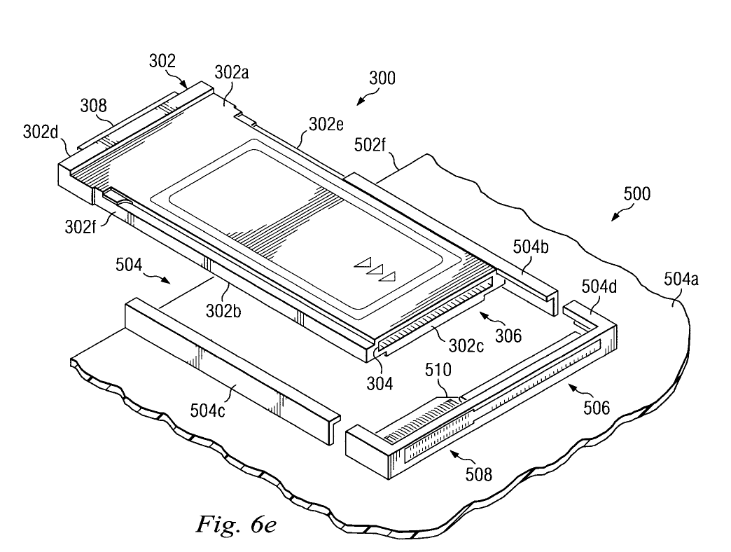

Referring now to FIG. 6a, a method 600 for electrically coupling an IHS card to an IHS is illustrated. The method 600 begins at step 602 where an IHS chassis is provided. The IHS chassis 500, illustrated in FIGS. 5a, 5b and 5c, is provided. The method 600 then proceeds to step 604, where the IHS card functionality required is determined and the appropriate IHS card is selected. In an embodiment, the functionality required may require the IHS card provide a connection between the host IHS and a docking station or port replicator. In an embodiment, the selected IHS card may include an antenna for wireless communications, a variety of card connectors for attachment to a peripheral devices including, but not limited to projectors, communication devices, physics processing units, TV tuners and SmartCard readers, a connector capable of Bluetooth communication, connectors for wired communications, or a variety of other capabilities known in the art. The IHS card selected may be for example, the conventional ExpressCard/54™ IHS card 200 described above in reference to FIG. 2, the conventional ExpressCard/34™ IHS card 300, described above in reference to FIG. 3, or the enhanced IHS card 400 described above in reference to FIGS. 4a, 4b and 4c. The method 600 concludes with step 606 where the selected card is coupled to the IHS chassis and electrically coupled to the IHS by means of the IHS connectors.

Referring now to FIGS. 4a, 4b, 4c, 5a, 5b, 5c, 6a, 6b and 6c, in an embodiment, in step 604 of the method 600, the enhanced IHS card 400, described above in reference to FIGS. 4a, 4b and 4c, is selected. The method 600 then proceeds to step 606 wherein the IHS card 400 is electrically coupled to the IHS chassis 500. The IHS card 400 is positioned adjacent the IHS chassis 500 such that the front edge 402d is substantially in alignment with the IHS card slot 504 of the IHS chassis 500. The IHS card 400 is then moved such that it enters the IHS card slot 504 and engages the side rails 504b and 504c to align the IHS card 400 in the IHS card slot 504. As the IHS card 400 continues to move through the IHS card slot 504, the IHS card connector 410 mates with the IHS connector 508 and the IHS card connector 408 mates with the IHS connector 506. As illustrated above in FIGS. 4a, 4b and 5b, the IHS card connector 410 has the same style as the IHS connector 508 and the IHS card connector 408 has the same style as the IHS connector 506 to ensure proper mating.

With the IHS card connectors 408 and 410 electrically coupled to the IHS connectors 506 and 508, respectively, the IHS card 400 buses 412a, 412b, 412c, 412d, 412e and 412f are electrically coupled to the IHS 500 buses 514a, 514b, 514c, 514d, 514e and 514f, respectively, as shown in FIG. 6c. The interfaces provided by the IHS card connector 408 and the IHS connector 506 are defined by an industry standard, such as the ExpressCard™ Standard. The PCI Express buses 412a and 514a electrically couple the host chip set 512a to the IHS card connector 404 through the IHS connector 506 and the IHS card connector 408 and are operable to transmit a signal between the host chip set 512a and the IHS card connector 404. The USB 2.0 buses 412b and 514b electrically couple the host chip set 512a to the IHS card connector 404 through the IHS connector 506 and the IHS card connector 408 and are operable to transmit a signal between the host chip set 512a and the IHS card connector 404. The enhanced IHS card 400 also allows for additional functionality beyond those defined by the ExpressCard™ Standard and may include the power bus 412c, the video bus 412d, the audio bus 412e, and the antenna signal bus 412f. The power buses 412c and 514c electrically couple the battery charger 512b to the IHS card connector 404 through the IHS connector 508 and the IHS card connector 410 and are operable to transmit power between the battery charger 512b and the IHS card connector 404. In an embodiment, a peripheral device connected to the IHS card connector 404 receives power from the battery charger 512b. This peripheral device may be, for example, a physics processing unit (PPU), a TV tuner card, or a miniature projector. In an embodiment, the power buses 412c and 514c are used to transmit power from a docking station or port replicator to the IHS chassis 500. In an embodiment, the power supplied is sufficient to be the sole source of power for the IHS chassis 500 and additional AC power is not required. The video buses 412d and 514d electrically couple the graphics processor 512c to the IHS card connector 404 through the IHS connector 508 and the IHS card connector 410 and are operable to transmit a signal between the graphics processor 512c and the IHS card connector 404. In an embodiment, a peripheral device coupled to the IHS card by the IHS card connector 404 is operable to use the graphics processor 512c to provide video output. The audio buses 412e and 514e electrically couple the audio processor 512d to the IHS card connector 404 through the IHS connector 508 and the IHS card connector 410 and are operable to transmit a signal between the audio processor 512d and the IHS card connector 404. The antenna signal buses 412f and 514f electrically couple the communications processor 512e to the IHS card connector 404 through the IHS connector 508 and the IHS card connector 410 and are operable to transmit a signal between the communications processor 512e and the IHS card connector 404. In an embodiment, the antenna signal buses 412f and 514f provide a signal from the IHS network or modem to a docking station. In an embodiment, the antenna signal bus transmits a signal for wireless capabilities, such as, for example, WWAN, WLAN, DVB-H/T, or other wireless signals as known in the art, between the IHS chassis 500 and an antenna. In an embodiment, the antenna is the card connector 404. Other buses may be present, as well as the buses enumerated may function in a variety of ways, for example, the buses may couple different IHS components than those enumerated above to the IHS card 400.

Referring now to FIGS. 2, 5a, 5b, 5c, 6a and 6d, in an embodiment, in step 604 of the method 600, the conventional ExpressCard/54™ IHS card 200, described above in reference to FIG. 2, is selected. The method 600 then proceeds to step 606 wherein the IHS card 200 is electrically coupled to the IHS chassis 500. The IHS card 200 is positioned adjacent the IHS chassis 500 such that the front edge 204c is substantially in alignment with the IHS card slot 504 of the IHS chassis 500. The IHS card 200 is then moved such that it enters the IHS card slot 504 and engages the side rails 504b and 504c to align the IHS card 200 in the IHS card slot 504. As the card continues to move, the IHS card connector 210 mates with the IHS connector 506. The IHS card connector 210 and the IHS connector 506 are 26 position beam-on-blade type connectors as defined by the ExpressCard™ Standard, their mating providing electrical interfaces between the IHS chassis 500 and the IHS card 200. In an embodiment, the electrical interfaces provided may include PCI Express and USB 2.0 as defined in the ExpressCard™ Standard.

Referring now to FIGS. 3, 5a, 5b, 5c and 6e, in an embodiment, in step 604 of the method 600, the conventional ExpressCard/34™ IHS card 300, described above in reference to FIG. 3, is selected. The method 600 then proceeds to step 606 wherein the IHS card 300 is electrically coupled to the IHS chassis 500. The IHS card 300 is positioned adjacent the IHS chassis 500 such that the front edge 302c is substantially in alignment with the IHS card slot 504 of the IHS chassis 500 and the side edge 302e is adjacent the side rail 504b. The IHS card 300 is then moved such that it enters the IHS card slot 504. The side rail 504b and the guide member 510 engage the IHS card 300 to properly align the IHS card 300 in the IHS card slot 504. As the card continues to move, the IHS card connector 306 mates with the IHS connector 506. The IHS card connector 306 and the IHS connector 506 are 26 position beam-on-blade type connectors as defined by the ExpressCard™ Standard, their mating providing electrical interfaces between the IHS chassis 500 and the IHS card 300. In an embodiment, the electrical interfaces provided may include PCI Express and USB 2.0 as defined in the ExpressCard™ Standard.

Thus, an enhanced IHS card is provided that is operable to electrically couple to a host IHS and provide additional functionality to the IHS. The enhanced IHS card interfaces with the IHS in part by way of an IHS connector that is compliant to the ExpressCard™ Standard and provides additional functionality to the IHS relative to a conventional ExpressCard™ through a second connector on the IHS card that engages a second IHS connector.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

1. An information handling system card (IHS card), comprising:
a base having a first end;
a first card connector located on the first end and operable to electrically couple to a first information handling system connector (IHS connector) located on an information handling system (IHS), wherein the first IHS connector is operable to electrically couple an IHS card compliant to the ExpressCard™ Standard to the IHS; and
a second card connector located on the first end and adjacent to the first card connector wherein the second card connector is operable to electrically couple to a second IHS connector located on the IHS.

2. The IHS card of claim 1, further comprising:
a second end located opposite the first end, wherein a third card connector is located on the second end and operable to electrically couple the IHS card to a peripheral device.

3. The IHS card of claim 2, wherein the peripheral device comprises a docking station.

4. The IHS card of claim 2, further comprising:
a power bus electrically coupled to the second card connector and operable to transmit power from the IHS to the peripheral device.

5. The IHS card of claim 1, further comprising:
a power bus electrically coupled to the second card connector and operable to transmit power through the IHS card to the IHS, wherein the transmitted power comprises the exclusive power supply of the IHS.

6. The IHS card of claim 1, wherein the second connector provides a video bus interface.

7. The IHS card of claim 1, wherein the first connector complies with the Expresscard™ Standard for connector style and functional interfaces.

8. The IHS card of claim 1, wherein the IHS card provides interfaces required by the Expresscard™ Standard and at least one additional interface that is electrically coupled to the IHS by the second card connector, wherein the at least one additional interface is one of a power bus, audio bus, video bus, and antenna signal bus interface.

9. The IHS card of claim 1, wherein the first end is approximately 54 mm in length.

10. The IHS card of claim 1, wherein the first card connector is a 26 position beam-on-blade connector.

11. An information handling system (IHS), comprising:
an IHS chassis;
a processor located in the IHS chassis;
an information handling system card (IHS card) slot defined by the chassis;
a first information handling system connector (IHS connector) located within the IHS card slot and electrically coupled to the processor; and
a second IHS connector located within the IHS card slot adjacent to the first IHS connector and electrically coupled to the processor, wherein the first IHS connector is operable to electrically couple an IHS card compliant to the ExpressCard™ Standard to the IHS, and wherein the second IHS connector is operable to electrically couple an IHS card to the IHS.

12. The IHS of claim 11, wherein the second IHS connector provides a video bus interface.

13. The IHS of claim 12, further comprising:
a graphics processor, whereby the video bus interface is electrically coupled to the graphics processor.

14. The IHS of claim 11, wherein the second IHS connector provides a power bus interface.

15. The IHS of claim 11, wherein the first IHS connector provides a USB interface and a PCI Express interface and the second IHS connector provides at least one additional interface, wherein the at least one additional interface is one of a video bus, power bus, audio bus, and antenna signal bus interface.

16. The IHS of claim 11, wherein the IHS card slot is operable to accept an IHS card with a width of approximately 54 mm.

17. A method of coupling an information handling system card (IHS card) to an information handling system (IHS) comprising:
providing an IHS chassis defining a slot and comprising a first connector operable to electrically couple an IHS card compliant to the ExpressCard™ Standard to the IHS and a second connector located adjacent the first connector;
determining the IHS card functionality required for the IHS use; and
electrically coupling an IHS card providing the determined functionality requirements to the IHS.

18. The method of claim 17, wherein the IHS card comprises at least one of a USB interface and a PCI Express bus interfaces operable to electrically couple to the first connector of the IHS chassis.

19. The method of claim 17, wherein the IHS card comprises one of a video bus, power bus, audio bus, and antenna signal bus interfaces operable to electrically couple to the second connector of the IHS chassis.

20. The method of claim 17, wherein the IHS card is an ExpressCard/54™.
